(19) United States
(12) Patent Application Publication
(10) Pub. No.: US 2007/0144672 A1
(43) Pub. Date: Jun. 28, 2007

(54) Plasma producing method and apparatus as well as plasma processing apparatus

(75) Inventors: Kenji Kato, Kyoto-shi (JP); Hiroshige Deguchi, Kyoto-shi (JP); Hitoshi Yoneda, Kyoto-shi (JP); Kiyoshi Kubota, Kyoto-shi (JP); Akinori Ebe, Kyoto-shi (JP); Yuichi Setsuhara, Osaka (JP)

Correspondence Address: RADER FISHMAN & GRAUER PLLC, LION BUILDING, 1233 20TH STREET N.W., SUITE 501, WASHINGTON, DC, 20036, US

(73) Assignees: NISSIN ELECTRIC CO., LTD., Kyoto-Shi (JP); EMD CORPORATION, Kyoto-Shi (JP)

(21) Appl. No.: 11/586,508

(22) Filed: Oct. 26, 2006

(30) Foreign Application Priority Data
Oct. 27, 2005 (JP) 2005-312681
Jun. 29, 2006 (JP) 2006-178857

(51) Int. Cl. C23F 1/00; C23C 16/00

(52) U.S. Cl. 156/345.48; 118/723 I

(57) ABSTRACT

Plasma producing method and apparatus as well as plasma processing apparatus including the plasma producing apparatus wherein one or more high-frequency antennas are arranged in a plasma producing chamber, and a high-frequency power is applied to a gas in the chamber from the antenna(s) to produce inductively coupled plasma. Impedance of the high-frequency antenna is set in a range of 45 Ω or lower.

### CROSS-REFERENCE TO RELATED APPLICATION

This invention is based on Japanese Patent application No. 2005-312681 filed in Japan on Oct. 27, 2005 and Japanese Patent application No. 2006-178857 filed in Japan on Jun. 29, 2006, the entire contents of which are hereby incorporated by reference.

### BACKGROUND OF THE INVENTION

1. Field of the Invention

The invention relates to a plasma producing method and apparatus for producing gas plasma as well as a plasma processing apparatus using the plasma producing apparatus, i.e., a plasma processing apparatus effecting intended processing on a work to be processed in plasma.

2. Description of the Related Art

Plasma is used, e.g., in plasma CVD method and apparatus forming a film in plasma, method and apparatus forming a film by effecting sputtering on a sputter target in plasma, method and apparatus performing etching in plasma, and method, apparatus and the like used for performing ion implantation or ion doping by extracting ions from plasma. Further, the plasma is used in various apparatuses utilizing the plasma such as apparatuses producing various semiconductor devices (e.g., thin-film transistors used in liquid crystal displays or the like), material substrates thereof or the like by using the foregoing methods and/or apparatuses.

Various types of plasma producing methods and apparatuses have been known and, for example, such types have been known that produce capasitively coupled plasma, produce inductively coupled plasma or ECR (Electron Cyclotron Resonance) plasma or produce microwave plasma.

Among them, the plasma producing method and apparatus producing the inductively coupled plasma are configured to obtain plasma of extremely high density and uniformity in a plasma producing chamber and, for this purpose, has a high-frequency antenna for the plasma producing chamber for producing the inductively coupled plasma by applying a high-frequency power from the high-frequency antenna to a gas in the chamber. More specifically, the high-frequency power is supplied to the high-frequency antenna to generate an induction electromagnetic field in the plasma producing chamber, and the induction electromagnetic field produces the inductively coupled plasma.

The high-frequency antenna may be arranged outside the plasma producing chamber, but it is also proposed to arrange it inside the plasma producing chamber for improving use efficiency of the supplied high-frequency power and other purposes.

For example, it is described in JP2001-35697A that a high-frequency antenna is arranged inside a plasma producing chamber to increase the use efficiency of applied high frequency power.

The foregoing publication mentions the following: when the antenna is arranged in the plasma producing chamber, (1) a marked rise of electric potential occurs due to capacitive coupling in the conductive portion of the antenna by an increase of the density of plasma because of increase of applied high-frequency power so that an abnormal discharge is caused in the plasma producing chamber, (2) the increase in capacitive coupling raises the amplitude of the high-frequency power applied to the plasma and induces turbulence of the plasma, resulting in greater fluctuation of the plasma in effecting etching and formation of film (e.g. increase of ion incidence energy) which may be likely to give a damage due to the plasma to the work or the like, and (3) therefore, it is important that the applied high-frequency voltage is changed to a low-level action voltage, and for this purpose, reduction of the antenna inductance and suppression of the capacitive coupling are required.

The publication also states that the high-frequency antenna can be formed of a linear conductor which is terminated without circling and has a planar structure (two-dimensional structure) which can reduce the inductance of the antenna in order to suppress increase of inductance due to the use of larger antenna.

An electron temperature (in other words, energy of electrons) in the plasma affects cutting of interatomic coupling of a substance exposed to the plasma, and the higher electron temperature causes cutting of the interatomic coupling to a higher extent. In the plasma processing, therefore, it is desired to control the electron temperature of the plasma and particularly to lower the electron temperature, e.g., for the purpose of suppressing damages to a work and the like due to plasma, or performing desired etching processing.

For example, in the case where a silicon thin film for a bottom-gate-type TFT is formed by a plasma CVD method, such a method is generally employed that the silicon thin film is formed on a substrate on which a gate insulating film (e.g., made of silicon nitride, silicon oxide or a mixture thereof) was deposited. When the electron temperature of the plasma is high when forming the silicon thin film, defects may occur, e.g., at the gate insulating film or the silicon thin film.

In connection with this matter, JP11-74251A has disclosed that an ion temperature lowers when an electron temperature in plasma becomes equal to 3 eV or lower in the plasma CVD method, and therefore, ion damages to a target substrate can be lowered in the plasma CVD.

As a manner of setting the electron temperature of 3 eV or lower, it is disclosed to generate higher-density plasma in a projection portion of the plasma producing chamber (vacuum container), in which a static magnetic field for controlling the plasma state is not present, than in the vicinity of the work substrate.

JP2004-311975A has disclosed that excessive decomposition of a material gas is prevented to form a good insulating film in the plasma CVD method by keeping the electron temperature at 3 eV or lower in a plasma generating space.

As a manner of setting the electron temperature at 3 eV or lower, it is disclosed to produce microwave plasma, and to employ a plane antenna member that is connected to a waveguide of the microwave and is provided with a large number of slits in a peripheral direction of the antenna member.

However, the JP2001-35697A has not referred to suppression of the electron temperature of the plasma.

The JP11-74251A and JP2004-311975A have referred to suppression of the electron temperature. For such suppression, the former has disclosed that the higher-density plasma is generated in the projection portion of the plasma producing chamber (vacuum chamber), in which a static magnetic field for controlling the plasma state is not present, than in the vicinity of the work substrate. According to this structure, the plasma producing chamber (vacuum container) must have the projection portion in which a static magnetic field for controlling the plasma state is not present.

The latter has disclosed the structure producing the microwave plasma, and employing the plane antenna member that is connected to the waveguide of the microwave and is provided with the large number of slits in a peripheral direction of the antenna member. It is necessary to prepare the antenna member having such a structure.

### SUMMARY OF THE INVENTION

Accordingly, a first object of the invention is to provide a plasma producing method in which at least one high-frequency antenna is arranged in a plasma producing chamber, and inductively coupled plasma is generated by applying a high-frequency power from the high-frequency antenna to a gas in the plasma producing chamber, and particularly a plasma producing method that can keep a low electron temperature in the plasma more readily than a conventional method.

A second object of the invention is to provide a plasma producing apparatus in which at least one high-frequency antenna is arranged in a plasma producing chamber, and inductively coupled plasma is generated by applying a high-frequency power from the high-frequency antenna to a gas in the plasma producing chamber, and particularly a plasma producing apparatus that can keep a low electron temperature in the plasma more readily than a conventional apparatus.

A third object of the invention is to provide a plasma processing apparatus that can satisfactorily perform intended processing on a work to be processed while suppressing damages which may be caused to the work and the like by plasma.

A fourth object of the invention is to provide a plasma processing apparatus that can satisfactorily perform intended processing on a work to be processed while suppressing damages which may be caused to the work and the like by plasma, and further can perform the plasma processing while suppressing unpreferable adhesion and mixture of impurities.

The inventors have conducted study for achieving the above objects, and have found the following.

In a plasma producing method and apparatus wherein at least one high-frequency antenna is arranged in a plasma producing chamber and inductively coupled plasma is produced by applying a high-frequency power to a gas in the plasma producing chamber, there is a relative relation like a linear function between impedance of the high-frequency antenna and electron temperature of the inductively coupled plasma so that when based on the relation, the impedance of the high-frequency antenna is predetermined in a range of 45 Ω(ohm) or lower, more preferably 15 Ω(ohm) or lower, the electron temperature of the plasma can be controlled to a lower level relatively readily (e.g. 3 eV or lower, more preferably 1 eV or lower).

Even in the case where the number of antennas is plural, when the impedance of each antenna is predetermined as 45 Ω or lower, more preferably 15 Ω or lower, the electron temperature of plasma can be controlled to a low level (e.g. 3 eV or lower , more preferably 1 eV or lower).

Based on the above findings, the invention provides, for achieving the foregoing first and second objects, the following method and apparatus for producing plasma.

(1) Plasma Producing Method

A plasma producing method in which at least one high-frequency antenna is arranged in a plasma producing chamber, and inductively coupled plasma is produced by applying a high-frequency power from the high-frequency antenna to a gas in the plasma producing chamber, wherein impedance of each high-frequency antenna is set in a range of 45 Ω(ohm) or lower.

(2) Plasma Producing Apparatus

A plasma producing apparatus in which at least one high-frequency antenna is arranged in a plasma producing chamber, and inductively coupled plasma is generated by applying a high-frequency power from the high-frequency antenna to a gas in the plasma producing chamber, wherein impedance of each high-frequency antenna is set in a range of 45 Ω(ohm) or lower.

This invention provides the following plasma processing apparatus to achieve the third object.

(3) Plasma Processing Apparatus

A plasma processing apparatus for effecting intended processing on a work to be processed, and including the plasma producing apparatus according to the invention.

Further, the invention provides, for achieving the foregoing fourth object, the following plasma processing apparatus.

(4) Plasma Processing Apparatus

This plasma processing apparatus is an apparatus of the type described above as apparatus (3), in which a holder is arranged in the plasma producing chamber for holding the work with its plasma processing target surface opposed to the high-frequency antenna, and at least a part of an inner surface of a chamber wall of the plasma producing chamber is covered with an electrically insulating material.

The foregoing and other objects, features, aspects and advantages of the present invention will become more apparent from the following detailed description when taken in conjunction with the accompanying drawings.

### BRIEF DESCRIPTION OF THE DRAWINGS

FIG. 1 is a view showing an example of a plasma producing apparatus according to the invention.

FIG. 2 is a view showing relation between antenna impedance and plasma electron temperature when one antenna is used.

FIG. 3 is a view showing another example of a plasma producing apparatus according to the invention.

FIG. 4 is a view showing relation between antenna impedance in use of two antennas arranged in a fashion of parallel connection and plasma electron temperature.

FIG. 5 is a view showing relation, when the electron temperature is the same, between the antenna impedance in use of single antenna and the antenna impedance in use of two antennas.

FIG. 6 is a view showing another example of a plasma producing apparatus according to the invention.

FIG. 7 is a view showing an example (plasma CVD apparatus) of a plasma processing apparatus according to the invention.

FIG. 8 (A) is a view showing another example (plasma CVD apparatus) of a plasma processing apparatus according to the invention.

FIG. 8 (B) is a bottom view of a top wall of a plasma producing chamber in the plasma processing apparatus shown in FIG. 8 (A).

FIG. 9 is a view showing another example (plasma CVD apparatus) of a plasma processing apparatus according to the invention.

FIG. 10 (A) is a view showing another example (plasma CVD apparatus) of a plasma processing apparatus according to the invention.

FIG. 10 (B) is a bottom view of a top wall of a plasma producing chamber in the plasma processing apparatus shown in FIG. 10 (A).

### DESCRIPTION OF THE PREFERRED EMBODIMENTS

A plasma producing method of a preferred embodiment of the invention is fundamentally as follows.

A plasma producing method for producing inductively coupled plasma by arranging at least one high-frequency antenna in a plasma producing chamber, and applying a high-frequency power to a gas in the plasma producing chamber from the high-frequency antenna, wherein impedance of each high-frequency antenna is predetermined in a range of 45 Ω(ohm) or lower.

A plasma producing apparatus of a preferred embodiment of the invention is fundamentally as follows.

A plasma producing apparatus for producing inductively coupled plasma by arranging at least one high-frequency antenna in a plasma producing chamber, and applying a high-frequency power to a gas in the plasma producing chamber from the high-frequency antenna, wherein impedance of each high-frequency antenna is predetermined in a range of 45 Ω(ohm) or lower.

In the plasma producing method and apparatus, the impedance of each high-frequency antenna may be predetermined in a range of 15 Ω or lower to suppress the electron temperature in the inductively coupled plasma to a lower level according to the purpose of the inductively coupled plasma and others.

The impedance Z of the high-frequency antenna is represented by the formula
Z=R (resistance component of antenna)+jωL, since the antenna serves as a resistor and a coil.

“L” is inductance component of antenna. “ω” is frequency and “j” is identified from j²=−1.

When a plurality of high-frequency antennas are arranged, the high-frequency antennas are connected in a fashion of parallel connection and the impedance of each of the high frequency antennas is predetermined as 45 Ω or lower.

As an example of each of the high-frequency antennas, a 2-dimensional structure antenna is exemplified that terminates without circling (antenna having a plane structure). For example, an antenna is usable which is produced by bending a linear or strip-like conductor (e.g., bending the conductor into a U-shaped or substantially U-shaped form).

A plasma processing apparatus of an embodiment of the invention is fundamentally an apparatus for effecting intended processing on a work to be processed in plasma, and particularly a plasma processing apparatus including any one of the foregoing plasma producing apparatuses.

In this plasma processing apparatus using the foregoing plasma producing apparatus according to the invention, the plasma can be controlled to keep a low electron temperature. Therefore, the apparatus can suppress damages to the work and the like due to the plasma, and can effect the intended processing on the work.

As the plasma processing apparatus of a preferred embodiment of the invention, an apparatus can be mentioned which is the above-mentioned type apparatus, wherein a holder is arranged in the plasma producing chamber for holding the work with its plasma processing target surface opposed to the high-frequency antenna, and at least a part of an inner surface of a chamber wall of the plasma producing chamber is covered with an electrically insulating member.

When the wall of the plasma producing chamber is exposed to the plasma, components of the chamber wall may be physically and/or chemically brought out, and such components may adhere to or move into the work or a film formed on the work (in the case where the plasma processing apparatus is a film deposition apparatus) so that the intended plasma processing may be hindered. In connection with this matter, movement of unpreferable chamber wall components from the chamber wall can be suppressed by covering at least a part of the inner surface of the wall of the plasma producing chamber with the electrically insulating member.

In the above plasma processing apparatus, the intended processing is effected on the work similarly to the aforementioned plasma processing apparatus and further can be performed, e.g., while suppressing damages to the work and the like due to the plasma, and further the plasma processing can be performed while suppressing adhesion and mixing of unpreferable impurities.

In the plasma processing apparatus, the inner surface of the plasma producing chamber wall may be entirely covered with the electrically insulating member. In this case, however, the plasma potential may rise, and the plasma may cause unignorable damages to the work or the film formed on the work (in the case where the plasma processing apparatus is a film deposition apparatus).

The following preferable examples may be employed for covering the inner surface of the chamber wall with the electrically insulating member. In the following examples, the electrically insulating member covers a portion of the inner surface of the chamber wall, and particularly covers the portion near the antenna where the plasma density becomes high.

(1) The electrically insulating member covers an inner surface of a portion of the plasma producing chamber wall where the high-frequency antenna is arranged, and to which a plasma processing target surface of the work held by the holder is opposed.

(2) The electrically insulating member covers an inner surface of a portion of the plasma producing chamber wall where the high-frequency antenna is arranged, and to which a plasma processing target surface of the work held by the holder is opposed as well as an inner surface of a side peripheral portion of the plasma producing chamber wall surrounding sideways the holder.

(3) The electrically insulating member locally covers each surface area surrounding the high-frequency antenna and including a surface portion neighboring to the antenna, which area is in an inner surface of a portion of the plasma producing chamber wall where the high-frequency antenna is arranged.

In any one of the above cases, various types of apparatuses utilizing plasma can be mentioned as the plasma processing apparatus. For example, the plasma processing apparatus may be a plasma CVD apparatus, an apparatus forming a film by effecting sputtering on a sputter target in plasma, an etching apparatus using plasma, an apparatus performing ion implantation or ion doping by extracting ions from plasma, or an apparatus using the above apparatus and producing various semiconductor devices (e.g., thin-film transistors used in liquid crystal displays and others), material substrates of the semiconductor devices or the like.

In a specific example, the plasma processing apparatus may be a thin film forming apparatus that includes a gas supply device supplying a gas into the plasma producing chamber for film formation, generates inductively coupled plasma by applying a high-frequency power from the high-frequency antenna to the gas supplied from the gas supply device into the plasma producing chamber, and form a thin film on the work under the plasma.

In another specific example of the plasma processing apparatus, the gas supply device supplies a gas for forming a silicon film on a plasma processing target surface of the work into the plasma producing chamber, and the film formed on the work is a silicon film.

In any one of the above cases, the electrically insulating member may be a member made of a material having resistivity of 1×10⁴ ohm·cm or more. The electrically insulating material exhibiting a resistivity of 1×10⁴ ohm·cm or more is, for example, at least one kind of material selected from quartz(SiO₂), alumina(Al₂O₃), aluminum nitride(AlN), yttria(Y₂O₃) and silicon carbide(SiC).

Plasma producing methods and apparatuses of embodiments of the invention will now be described with reference to the drawings.

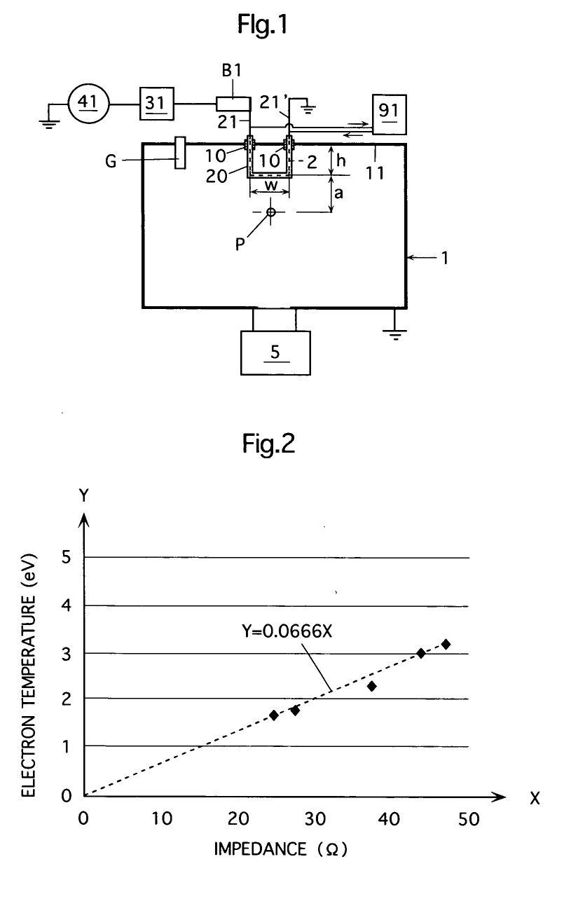

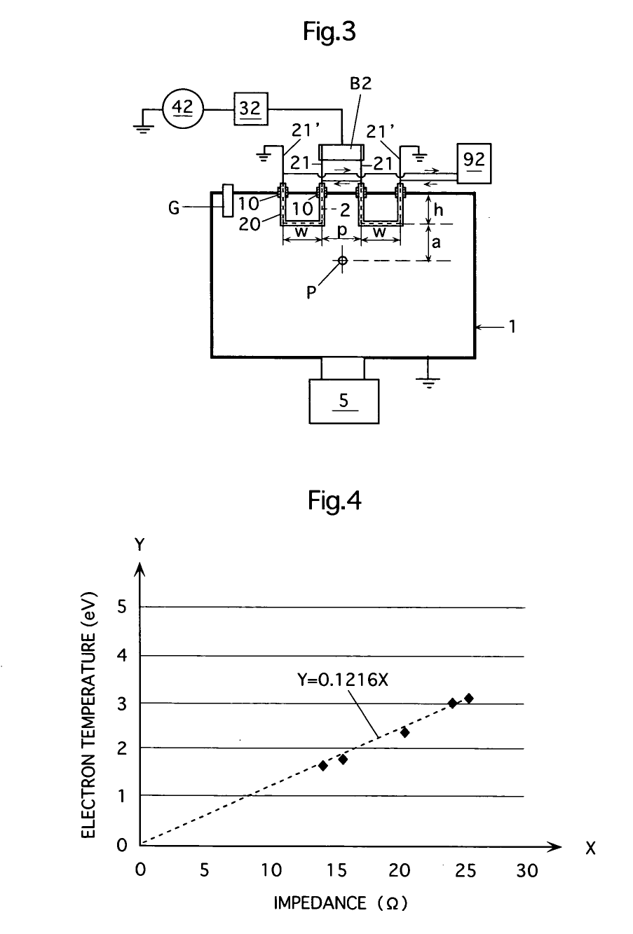

FIG. 1 shows an example of a plasma producing apparatus according to the invention. FIG. 3 shows another example of a plasma producing apparatus according to the invention.

The plasma producing apparatus in FIG. 1 includes a plasma producing chamber 1. A high-frequency antenna 2 is inserted into the plasma producing chamber 1 through a top wall 11 of the chamber 1, and is located in the chamber. The high-frequency antenna is covered with an insulating member 20, and is inserted together with the insulating member 20 through insulating members 10 arranged at the top wall 11. The antenna 2 in this example has a U- or substantially U-shaped form.

The antenna 2 has portions 21 and 21′ projected outward from the chamber through the chamber top wall 11. One portion 21 of these portions 21 and 21′ is connected to a power supply busbar B1. The busbar B1 is connected to a high-frequency power source 41 via a matching box 31. The other portion 21′ is grounded.

The plasma producing apparatus in FIG. 3 includes a plasma producing chamber 1. Two high-frequency antennas 2 are inserted into the plasma producing chamber 1 through a top wall 11 of the chamber and are located in the chamber. Each high-frequency antenna is covered with an insulating member 20 like the antenna in FIG. 1 and is passed through insulating members 10 on the top wall 11 together with the member 20.

Each antenna 2 in the plasma producing apparatus in FIG. 3 is a U-shaped or substantially U-shaped form like the antenna shown in FIG. 1. The two antennas 2 have the same size and are linearly arranged neighboring to each other with a space p between them on the same plane.

Two antennas in the plasma producing apparatus of FIG. 3 have portions 21, 21′ projected outward from the chamber. Neighboring portions 21, 21 are connected to a power supply busbar B2 common to the portions and the busbar B2 is connected to a high-frequency power source 42 via a matching box 32. The other projected portions 21′ are grounded. Namely these two antennas 2 are connected in parallel.

Both the plasma producing apparatuses in FIG. 1 and in FIG. 3 further include a gas inlet portion G for passing a predetermined gas into the plasma producing chamber 1, and an exhaust device 5 for exhausting the gas from the chamber to attain a predetermined plasma production pressure in the chamber 1.

Referring to the antenna, in each of the plasma producing apparatuses in FIG. 1 and FIG. 3, each antenna 2 is formed of an electrically conductive pipe, and the insulating member 20 covering the antenna 2 is an insulating pipe.

In the plasma producing apparatus shown in FIG. 1, it is configured that a coolant circulating device 91 passes a coolant (cooling water in this example) through the antenna 2 for cooling it as shown in the figure.

The electrically conductive pipe forming the antenna 2 is, in this example, a pipe having a circular section and formed of copper. However, it is not restrictive and may be a rod having a circular section and made of other electrically conductive material such as copper, aluminum or the like

The insulating member 20 covering the antenna 2 is a quartz pipe in this example to which it is not limited. The member 20 may be a pipe formed of alumina or other insulating materials. The member 20 need not be a pipe and may be formed by coating the antenna 2 with an insulating material.

In the plasma producing apparatus in FIG. 1, impedance of the antenna 2 is set to 45 Ω or lower. In the plasma producing apparatus in FIG. 3, impedance of each of the two antennas 2 is set to 45 Ω or lower.

According to the plasma producing apparatuses already described with reference to FIGS. 1 and 3, plasma can be produced as follows. The exhaust device 5 discharges a gas from the plasma producing chamber 1 to lower the chamber pressure below a predetermined plasma producing pressure. Then, a predetermined gas is introduced through the gas inlet portion G into the chamber 1 and the high-frequency power source supplies a high-frequency power to the antenna(s) 2 while setting and maintaining the predetermined plasma producing pressure in the chamber by the exhaust device 5. Thus, inductively coupled plasma suppressed in electron temperature can be produced in the chamber 1.

Description will be given as to the findings obtained that the electron temperature of plasma can be kept low by predetermining the impedance Z of antenna in a range of 45 Ω or lower in use of a single antenna, and by determining the impedance Z of each antenna at 45 Ω or lower in use of two or more antennas.

First, using a plasma producing apparatus of the type shown in FIG. 1 (apparatus with a single antenna), and employing 5 kinds of antennas of varied sizes, an experiment (Experiment 1) was performed by production of plasma under the same conditions except for using each antenna, respectively, to investigate the relation between the antenna impedance Z (Ω) and the electron temperature (eV) of produced plasma.

Also, using a plasma producing apparatus of the type shown in FIG. 3 (apparatus with two antennas), and employing two of each of antennas (5 kinds of sizes used in Experiment 1), an experiment (Experiment 2) was performed by formation of plasma under the same conditions as Experiment 1 except for the antennas to investigate the relation between the antenna impedance Z (Ω) and the electron temperature (eV) of produced plasma.

Five kinds of 1^{st} to 5^{th} antennas used in Experiments 1 and 2 were formed by bending circular-section pipes of copper with an outer diameter of ¼ inches (about 6.35 mm), and a pipe wall thickness of 1 mm into U-shaped or substantially U-shaped form like antennas shown in FIGS. 1 and 3 in which cooling water internally can pass. The insulating pipe covering the antenna is a quartz pipe with an outer diameter of 16 mm and an inner diameter of 12 mm). The antenna sizes are shown below.

| | W | H(h) | | TL |
|---|---|---|---|---|
| 1^{st} antenna | 55 mm | 225 mm | (75 mm) | 505 mm |
| 2^{nd} antenna | 55 mm | 250 mm | (100 mm) | 555 mm |
| 3^{rd} antenna | 100 mm | 300 mm | (150 mm) | 700 mm |
| 4^{th} antenna | 150 mm | 300 mm | (150 mm) | 750 mm |
| 5^{th} antenna | 150 mm | 350 mm | (200 mm) | 850 mm |

W = horizontal width
H = vertical length
h = vertical
length in chamber
TL = total length of antenna

Description is given below on the experiments 1 and 2.

### (1) Experiment 1 (Use of Single Antenna)

<Plasma Producing Conditions)

High-frequency power: power of 13.56 MHz and 1250 W was supplied to antenna

| | |
|---|---|
| Plasma production pressure: | 1.8 Pa |
| Kind and amount of supplied gas: | hydrogen gas, |
| | 300 cc/minute |

Initially, the plasma producing chamber was depressurized to the order of 10⁻⁵ Pa and thereafter hydrogen gas was supplied in an amount of 300 cc/minute and internal chamber pressure was kept at 1.8 Pa.

Inductively coupled plasma was produced using each of the 1^{st} to 5^{th} antennas which differ in size from each other to determine a relation between impedance Z of the antenna and electron temperature (eV) of the plasma by measuring the antenna impedance Z (Ω) and the electron temperature (eV) of the plasma.

The antenna impedance Z was determined by measuring a value corresponding to 13.56 MHz using a network analyzer (Agilent Technologies Company, E5061A). The network analyzer measured resistance R and jωL, separately. However, in this experiment, the resistance component R was less than 1 Ω, namely a negligible value so that the impedance of the antenna was defined as Z=jωL.

The electron temperature was measured with, as shown in FIG. 1, a Langmuir probe P located immediately under a central position of width of the antenna and spaced by a distance a (see FIG. 1) of 175 mm from the lower end of the antenna.

The measurement results are as follows.

| | Electron temperature (eV) | Impedance (Ω) |
|---|---|---|
| 1^{st} antenna | 1.7 | 24.6 |
| 2^{nd} antenna | 1.8 | 27.7 |
| 3^{rd} antenna | 2.3 | 37.4 |
| 4^{th} antenna | 3.0 | 43.8 |
| 5^{th} antenna | 3.2 | 47.1 |

FIG. 2 shows the measuring results on a X-Y plane wherein ordinate Y indicates electron temperatures and abscissa X indicates impedances.

The relation between Y (electron temperature) and X (impedance) is represented as substantially Y=0.0666X by a method of least squares.

As described above, the antenna impedances and the electron temperatures show a correlation like a linear function.

Therefore, it is clear that the electron temperature of plasma can be controlled by controlling the impedance.

From the relation of Y=0.0666X, it is seen that the impedance for obtaining 3 eV or lower which is preferable as an electron temperature is 45 Ω or lower, and that the impedance for obtaining 1 eV or lower which is more preferable as an electron temperature is 15 Ω or lower.

### (2) Experiment 2 (2 Antennas Arranged in a Fashion of Parallel Connection)

<Plasma Producing Conditions)

High-frequency power: power of 13.56 MHz and 2500 W was supplied to two antennas

| | |
|---|---|
| Plasma production pressure: | 1.8 Pa |
| Kind and amount of supplied gas: | hydrogen gas, |
| | 300 cc/minute |

Initially, the plasma producing chamber was depressurized to the order of 10⁻⁵ Pa. Then, hydrogen gas was supplied in an amount of 300 cc/minute and internal chamber pressure was kept at 1.8 Pa.

Inductively coupled plasma was produced using the 1^{st} to 5^{th} antennas, respectively, which differ in size from each other and were arranged in a fashion of parallel connection to determine a relation between the impedance (Z) of the two antennas connected in parallel and electron temperature (eV) by measuring the impedance Z (Ω) of the two antennas connected in parallel and the electron temperature of the plasma.

The antenna impedance Z was determined by measuring a value corresponding to 13.56 MHz using a network analyzer (Agilent Technologies Company, E5061A). However, in this experiment, the resistance component R was less than 1 Ω, namely a negligible value so that the impedance of the two antennas was defined as Z=jωL.

The electron temperature was measured with a Langmuir probe P located immediately under a central position of distance p (160 mm in this example) between the two antennas and spaced by a distance a (see FIG. 3) of 175 mm from the lower end of the antennas as shown in FIG. 3.

The measurement results are as follows.

| | Electron temperature (eV) | Antenna Impedance (Ω) |
|---|---|---|
| 1^{st} antenna (two) | 1.7 | 14.0 |
| 2^{nd} antenna (two) | 1.8 | 15.6 |
| 3^{rd} antenna (two) | 2.4 | 20.3 |
| 4^{th} antenna (two) | 3.0 | 24.0 |
| 5^{th} antenna (two) | 3.1 | 25.2 |

FIG. 4 shows the measuring results on a X-Y plane wherein the ordinate Y indicates electron temperatures and the abscissa X indicates impedances.

The relation between Y (electron temperature) and X (impedance) is represented as substantially Y=0.1216X according to the method of least squares.

As described above, the impedances and the electron temperatures regarding all the groups wherein the two antennas are connected in parallel show a correlation like a linear function. Therefore, it is clear that the electron temperature of plasma can be controlled by controlling the impedance.

From the relation of Y=0.1216X, it is seen that the antenna impedance for obtaining 3 eV or lower which is preferable as an electron temperature is 24.7 Ω or lower, and that the antenna impedance for obtaining 1 eV or lower which is more preferable as an electron temperature is 8.2 Ω or lower.

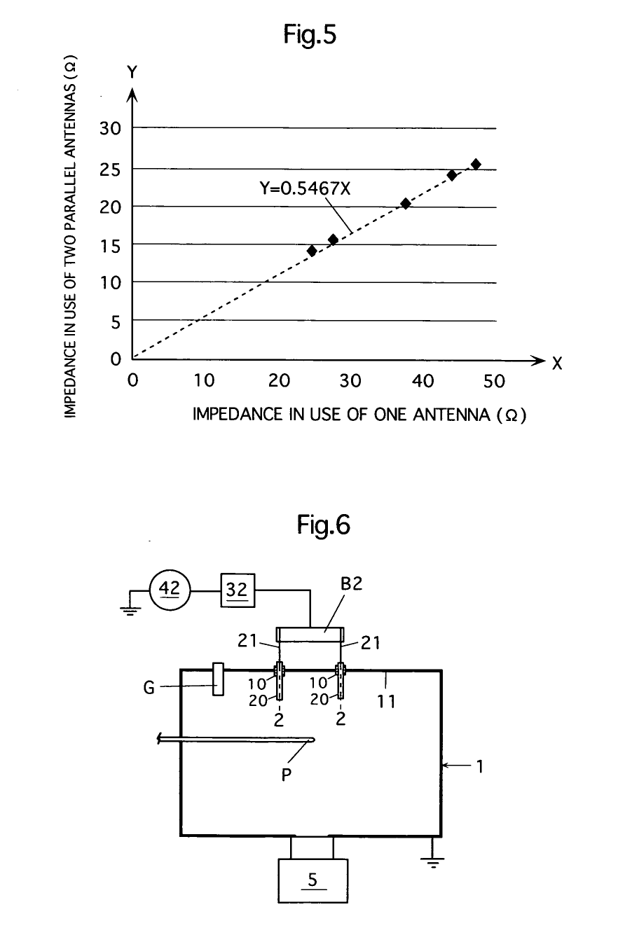

FIG. 5 shows the relation between the antenna impedance in use of single antenna and the antenna impedance in use of two antennas connected in parallel on a X-Y plane wherein the ordinate Y indicates impedances in use of two antennas arranged in parallel connection and the abscissa X indicates impedance in use of single antenna.

The relation of Y=0.5467X is derived by a method of least squares.

From this relation formula, it is seen that, for example, the impedance of 15 Ω affording an electron temperature of 1 eV or lower in use of single antenna results in 0.5467×15 Ω=8.2 Ω when using two antennas connected in parallel. If it is an X value in the relation formula Y=0.1216X in use of two antennas, 0.1216×8.2=1 eV is obtainable. Namely it is clear that in use of two antennas, the impedance of each of the two antennas should be 15 Ω or lower for obtaining an electron temperature of 1 eV or lower.

Similarly it is clear that even in use of two antennas, the impedance of each of the two antennas is 45 Ω or lower for obtaining an electron temperature of 3 eV or lower.

For example, when using two antennas arranged in a fashion of parallel connection wherein the impedance of one antenna is 45 Ω, it results in 0.5467×45 Ω=24.6Ω. Therefore if it is an X value in the relation formula Y=0.1216X in use of two antennas, 0.1216×24.6=2.99 eV results, whereby 3 eV or lower is obtainable.

The lower limit of antenna impedance may be, e.g., about 9 Ω which is lead from the foregoing experiments, although it is not restrictive.

More specifically, relation between antenna total length and antenna impedance is determined by plotting points showing antenna total length (each antenna total length×2 in use of two antennas) and antenna impedance on a X-Y plane wherein the abscissa X indicates antenna total lengths and the ordinate Y indicates antenna impedances regarding each of the 1^{st} to 5^{th} antennas, and determining the relation from the plotted points by a method of least squares. A relation of Y=0.0542X is obtained in use of single antenna in Experiment 1, whereas a relation of Y=0.0297X is obtained in use of two antennas arranged in parallel connection in Experiment 2.

If the minimum of the total length of a single antenna is, for example, about 170 mm from a practical viewpoint in consideration of working of antenna, supply of power to antenna, attachment of fittings for grounding of antenna, etc., the impedance is Y=0.0542×170=9.2 Ω from the relation of Y=0.0542X in use of single antenna.

Therefore, if the minimum of the total length of a single antenna is predetermined as about 170 mm or a little shorter from a practical viewpoint, the lower limit of the impedance of the single antenna is about 9 Ω.

Supposing the impedance of a single antenna is 9 Ω, an electron temperature of about 0.6 eV is obtained from the relation formula (Y=0.666X) between the electron temperature Y and the antenna impedance X obtained in Experiment 1.

The antenna impedance in use of two antennas arranged in a fashion of parallel connection is 0.5467×9=4.9 Ω from the relation formula shown in FIG. 5 and the electron temperature of about 0.6 eV is obtained from the relation formula Y=0.1216X (see FIG. 4) between the electron temperature Y and impedance X of two antennas obtained in Experiment 2.

The experiments were conducted using a hydrogen gas. Even when other kinds of gas such as rare-gas (argon gas or the like), silane gas, methane gas, nitrogen gas, oxygen gas or the like is used, plasma electron temperature can be 3 eV or lower by using each antenna at a predetermined impedance of 45 Ω or lower.

In the experiments described above, the 1^{st} to 5^{th} antennas were provided which had impedance varied by varying the antenna length. The antenna impedance can be varied by adjusting the thickness of antennas or the thickness and length thereof.

In the plasma producing apparatus described above, when employing two high-frequency antennas, the antennas were linearly arranged to neighbor to each other on the same plane as shown in FIG. 3, whereas the antennas may be opposed to each other in a fashion of parallel arrangement as shown in FIG. 6. Optionally the antennas may be arranged so that parts of antennas in widthwise direction cross each other which is not shown in the figure. In any way, when a plurality of antennas are used, the antennas are arranged in a fashion of parallel connection.

The plasma producing apparatuses described above can be used for providing various plasma processing apparatuses. For example, it is possible to provide plasma processing apparatuses such as a plasma CVD apparatus, an apparatus forming a film by effecting sputtering on a sputter target in plasma, an etching apparatus using plasma, an apparatus performing ion implantation or ion doping by extracting ions from plasma, and an apparatus using the above apparatus and producing various semiconductor devices (e.g., thin-film transistors used in liquid crystal displays and others), material substrates of the semiconductor devices or the like.

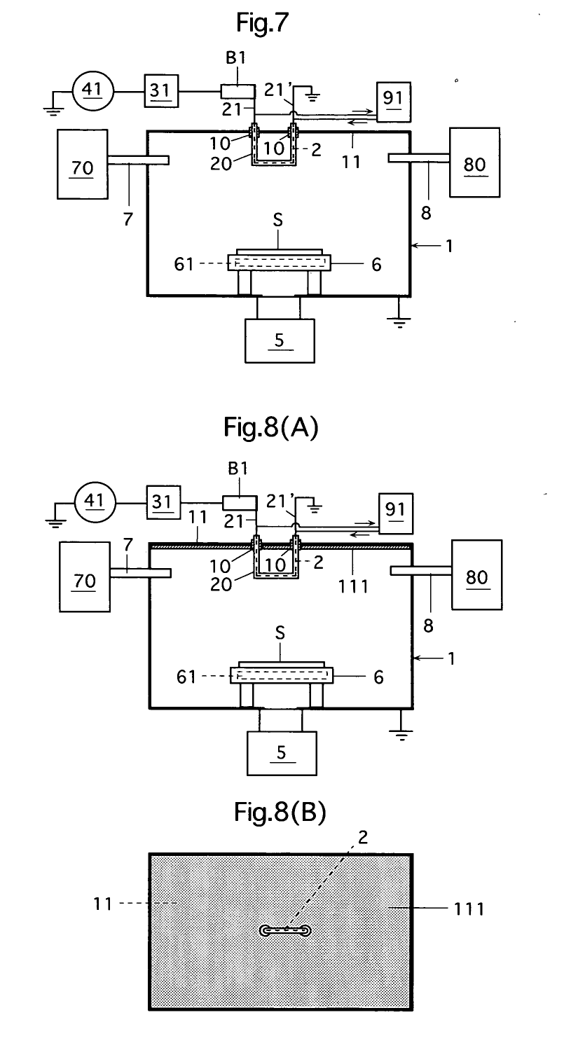

FIG. 7 shows an example of a plasma CVD apparatus using the plasma producing apparatus shown in FIG. 1. The plasma CVD apparatus in FIG. 7 is a silicon thin film forming apparatus and differs from the plasma producing apparatus in FIG. 1 in that the plasma producing chamber 1 serves also as a deposition chamber, a holder 6 (internally provided with a heater 61) is arranged in the chamber 1 for holding a film formation target substrate S, gas inlet pipes 7 and 8 are employed as the gas inlet portions, The pipe 7 is connected to a monosilane gas supply device 70 and the pipe 8 is connected to a hydrogen gas supply device 80. This plasma CVD apparatus can form a silicon thin film on the substrate S.

By the way, for example, silicon thin film forming apparatuses often employ such a structure that the wall of the deposition chamber is made of an alloy of aluminum having a high anticorrosion property with respect to a cleaning gas for cleaning silicon deposited on the deposition chamber wall in the silicon film forming processing by plasma of the cleaning gas. In this case, the aluminum may be derived from the deposition chamber wall when forming the silicon film on the substrate, and this aluminum serving as impurities may adhere onto or may move into the silicon film formed on the substrate.

In the plasma processing apparatus according to the invention, as already described, at least a part of the inner surface of the chamber wall of the plasma producing chamber may be covered with an electrically insulating member so that the plasma processing can be performed while suppressing adhesion and mixing of unpreferable impurities.

Examples of the above will now be described with reference to FIGS. 8(A), 8(B), 9, 10(A) and 10(B).

FIG. 8(A) shows a silicon thin film forming apparatus that differs from the silicon thin film forming apparatus (an example of the plasma processing apparatus) shown in FIG. 7 in that an electrically insulating plate 111 (a quartz plate in this example, but an alumina plate or the like can be employed) covers entirely the inner surface of the top wall 11 of the plasma producing chamber 1 where the high-frequency antenna 2 is arranged, and to which the film deposition target surface of the substrate S held by the holder 6 is opposed. FIG. 8(B) is a bottom view of the portion of the top wall 11 of the plasma producing chamber 1.

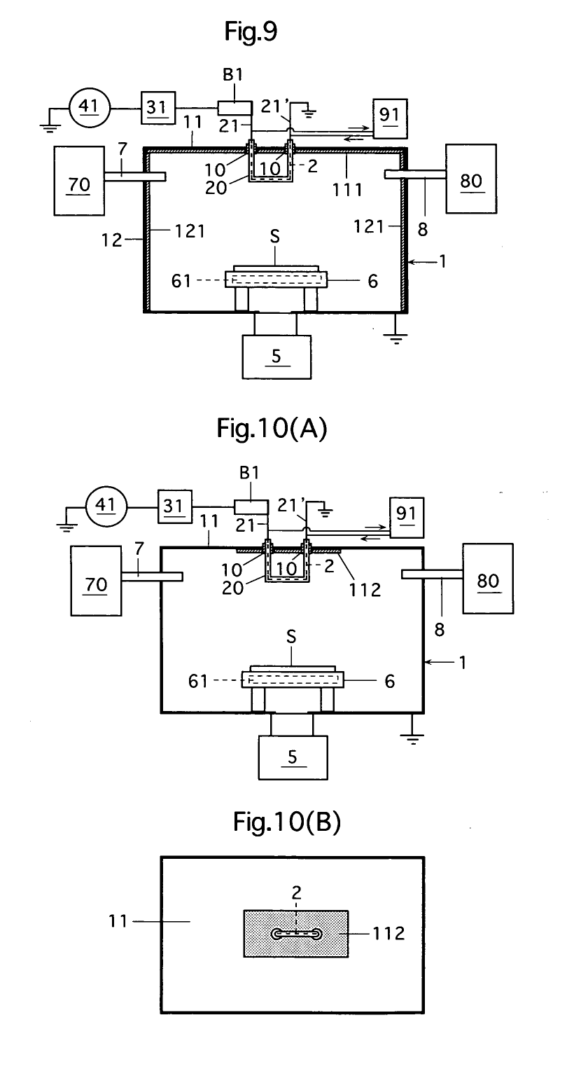

FIG. 9 shows a silicon thin film forming apparatus that differs from the silicon thin film forming apparatus shown in FIG. 7 in that electrically insulating members (quartz plates in this example) 111 and 121 cover the walls defining the plasma producing chamber 1, and particularly cover entirely the inner surface of the top wall 11 and the inner surface of the side peripheral wall 12 surrounding sideways the holder 6.

FIG. 10(A) shows a silicon thin film forming apparatus that differs from the silicon thin film forming apparatus shown in FIG. 7 in that an electrically insulating member (quartz plate in this example) 112 covers the wall defining the plasma producing chamber 1, and particularly covers locally an area of the inner surface of the top wall 11 neighboring to and located around the high-frequency antenna 2. FIG. 10(B) is a bottom view of the portion of the top wall 11 of the plasma producing chamber 1.

When at least a part of the inner surface of the wall of the plasma producing chamber is covered with a electrically insulation member, the inner surface of the plasma producing chamber wall may be entirely covered with the electrically insulating member. This configuration can sufficiently suppress adhesion and mixing of the aluminum originating from the plasma producing chamber wall onto or into the silicon film formed on the substrate S. However, when the electrically insulating member covers entirely the inner surface of the plasma producing chamber wall, the plasma potential rises, and the plasma may cause unignorable damages to the substrate S and the silicon film formed thereon. Therefore, in the silicon thin film forming apparatuses shown in FIGS. 8(A), 9 and 10(A), the electrically insulating member does not cover entirely the inner surface of the plasma producing chamber wall, but covers partially the inner surface.

When the silicon thin film forming apparatuses shown in FIGS. 7, 8(A), 9 and 10(A) have the plasma producing chamber 1 of which wall is made of alloy of aluminum, the aluminum originating from the plasma producing chamber may adhere to or move into the silicon film formed on the substrate S. The degree of this adhesion and movement (mixing) can be suppressed in the apparatuses provided with the electrically insulating member(s) as shown in FIGS. 8(A), 9 or 10(A) as compared with the apparatus in FIG. 7 not having the electrically insulating member covering the inner surface of the plasma producing chamber wall.

In the apparatus shown in FIG. 10(A), a total area of the quartz plate 112 covering the top wall 11 of the plasma producing chamber 1 is smaller than the total area of the quartz plate(s) of each of the apparatuses in FIGS. 8(A) and 9, and therefore the apparatus in FIG. 10(A) can suppress the adhesion and mixing of the aluminum onto or into the silicon film to a slightly lower extent than those in FIGS. 8(A) and 9. However, the apparatus in FIG. 10(A) is provided with the quarts plate 112 neighboring to the antenna 2 around which the plasma density becomes high, and therefore can suppress the adhesion and mixing of the aluminum to an extent that can practically make them ignorable. Further, the area of the quartz plate 112 covering the plasma producing chamber wall can be small, and this can suppress the rising of the plasma potential, and can suppress damages to the silicon film due to the plasma.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A plasma producing method in which at least one high-frequency antenna is arranged in a plasma producing chamber, and inductively coupled plasma is generated by applying a high-frequency power from the high-frequency antenna to a gas in the plasma producing chamber, wherein impedance of each high-frequency antenna is set in a range of 45 Ω or lower.

2. The plasma producing method according to claim 1, wherein
a plurality of high-frequency antennas are arranged in a fashion of parallel connection and impedance of each high-frequency antenna is set in a range of 45 Ω or lower.

3. The plasma producing method according to claim 1 or 2, wherein
the impedance of each high-frequency antenna is 15 Ω or lower.

4. A plasma producing apparatus in which at least one high-frequency antenna is arranged in a plasma producing chamber, and inductively coupled plasma is generated by applying a high-frequency power from the high-frequency antenna to a gas in the plasma producing chamber, wherein impedance of each high-frequency antenna is set in a range of 45 Ω or lower.

5. The plasma producing apparatus according to claim 4, wherein the impedance of each high-frequency antenna is 15 Ω or lower.

6. The plasma producing apparatus according to claim 4, wherein
a plurality of high-frequency antennas are arranged in a fashion of parallel connection and impedance of each high-frequency antenna is set in a range of 45 Ω or lower.

7. The plasma producing apparatus according to claim 6, wherein
the impedance of each high-frequency antenna is 15 Ω or lower.

8. A plasma processing apparatus for effecting intended processing on a work to be processed, comprising the plasma producing apparatus according to claim 4, 5, 6 or 7.

9. The plasma processing apparatus according to claim 8, wherein
a holder is arranged in said plasma producing chamber for holding said work with its plasma processing target surface opposed to said high-frequency antenna, and at least a part of an inner surface of a chamber wall of said plasma producing chamber is covered with an electrically insulating member.

10. The plasma processing apparatus according to claim 9, wherein
said electrically insulating member covers an inner surface of a wall portion of said plasma producing chamber where the high-frequency antenna is arranged and to which a plasma processing target surface of the work held by the holder is opposed.

11. The plasma processing apparatus according to claim 9, wherein
said electrically insulating member covers an inner surface of a wall portion of said plasma producing chamber where the high-frequency antenna is arranged and to which a plasma processing target surface of the work held by the holder is opposed as well as an inner surface of a side peripheral wall portion of said plasma producing chamber surrounding sideways said holder.

12. The plasma processing apparatus according to claim 9, wherein
said electrically insulating member locally covers each surface area surrounding the high-frequency antenna and including a surface neighboring to the antenna, which area is in an inner surface of a portion of the plasma producing chamber wall where the high-frequency antenna is arranged.

13. The plasma processing apparatus according to claim 9, wherein
said electrically insulating member is made of at least one kind of material selected from quartz, alumina, aluminum nitride, yttria and silicon carbide.

14. The plasma processing apparatus according to claim 8, wherein
said plasma processing apparatus is a thin film forming apparatus including a gas supply device supplying a gas into said plasma producing chamber for film formation, generating inductively coupled plasma by applying a high-frequency power from said high-frequency antenna to the gas supplied from the gas supply device into the plasma producing chamber, and forming a thin film on said work under the plasma.

15. The plasma processing apparatus according to claim 14, wherein
said gas supply device supplies the gas for forming a silicon film on a plasma processing target surface of said work into said plasma processing chamber, and the film formed on said work is a silicon film.
